(19) United States
(12) Patent Application Publication
(10) Pub. No.: US 2010/0184291 A1
(43) Pub. Date: Jul. 22, 2010

(54) AQUEOUS SLURRY COMPOSITION FOR CHEMICAL MECHANICAL POLISHING AND CHEMICAL MECHANICAL POLISHING METHOD

(75) Inventors: Dong-Mok Shin, Daejeon (KR); Eun-Mi Choi, Daejeon (KR); Seung-Beom Cho, Daejeon (KR); Hyun-Chul Ha, Daejeon (KR)

Correspondence Address: ROTHWELL, FIGG, ERNST & MANBECK, P.C., 1425 K STREET, N.W., SUITE 800, WASHINGTON, DC, 20005, US

(73) Assignee: LG CHEM, LTD., Seoul (KR)

(21) Appl. No.: 12/594,798

(22) PCT Filed: Feb. 26, 2009
(86) PCT No.: PCT/KR2009/000917

§ 371 Date: Apr. 1, 2010

(30) Foreign Application Priority Data
Feb. 29, 2008 (KR) 10-2008-0019103
Feb. 5, 2009 (KR) 10-2009-0009099

(51) Int. Cl. C09K 13/06; C09K 13/00; H01L 21/461

(52) U.S. Cl. 438/692; 252/79.1; 252/79.4; 257/E21.304

(57) ABSTRACT

The present invention relates to an aqueous slurry composition for chemical mechanical polishing that can show good polishing rate to the target layer, and yet has a high polishing selectivity and can maintain superior surface condition of the target layer after polishing, and a chemical mechanical polishing method.

The aqueous slurry composition for chemical mechanical polishing (CMP) includes abrasives; an oxidant; a complexing agent; and a polymeric additive including at least one selected from the group consisting of a polypropyleneoxide, a propyleneoxide-ethyleneoxide copolymer, and a compound represented by Chemical Formula 1.

### BACKGROUND OF THE INVENTION

(a) Field of the Invention

The present invention relates to an aqueous slurry composition for chemical mechanical polishing (CMP), and a chemical mechanical polishing method. And more particularly, the present invention relates to an aqueous slurry composition for chemical mechanical polishing that can show good polishing rate to the target layer, and yet has a high polishing selectivity and can maintain superior surface condition of the target layer after polishing, and a chemical mechanical polishing method.

(b) Description of the Related Art

High integration and high performance of a semiconductor device have continuously been required. Particularly, it is necessarily required to form a multi-layered wiring structure in order to achieve the high integration of the semiconductor device, and a planarization of each wiring layer to form an additional wiring layer is required in order to form the multi-layered wiring structure.

From the past, various methods of a reflow, a spin-on-glass (SOG) or an etchback, and the like have been used for the planarization of the wiring layer, however, these methods did not show satisfactory results according to the forming of the multi-layered wiring structure. On this account, chemical mechanical polishing (CMP) methods are widely applied for the planarization of the wiring layer, recently.

The CMP method is a method of contacting a polishing pad with a wiring layer and moving them relatively (for example, rotating a substrate on which the wiring layer is formed) while providing a slurry composition including abrasives and various chemical constituents between the polishing pad of the polishing device and the substrate on which the wiring layer is formed, so as to polish the wiring layer chemically by the action of the chemical constituents while mechanically polishing the wiring layer with the abrasives.

In general, silica or alumina is included in the slurry composition for the CMP method as the abrasive. However, there are problems of causing scratch, dishing, or erosion those deteriorate the reliability of the wiring layer because of high hardness of the abrasives.

Furthermore, an attempt to form the wiring layer with a copper is recently going on. The copper is a metal easy to cause a chemical reaction with the chemical constituents included in the slurry composition, and thus the polishing and the planarization is mainly accomplished by the chemical polishing rather than the mechanical polishing. On this account, there is a problem of that dishing is caused because even the part that should not be chemically polished is attacked by the chemical constituents, during the copper wiring layer is polished and planarized.

Because of the problem, the developments about a slurry composition or a polishing method those are able to maintain superior surface of the polished target layer such as a copper wiring layer by inhibiting scratch, dishing, erosion, and the like have continuously been required.

For example, there was an attempt to inhibit dishing by using a corrosion inhibitor like benzotriazole (Japan Patent Publication Hei 8-83780). That is, the reason of dishing that occurs during polishing the copper wiring layer is that the copper wiring layer is chemically attacked by the chemical constituents of an organic acid and the like in the dug parts among uneven parts of the copper wiring layer to be polished because the polishing pad does not reach to the dug parts and its mechanical force is not given to them, and there were attempts to reduce dishing and the like by inhibiting such chemical attack by using the corrosion inhibitor.

However, such use of the corrosion inhibitor even affects the mechanical polishing, and may deteriorate overall polishing rate and polishing speed of the whole copper wiring layer. That is, an excessive use of the corrosion inhibitor is required in order to reduce dishing generated in the copper wiring layer, but it is not preferable because the overall polishing rate and polishing speed are largely deteriorated in this case, and it is impossible to inhibit dishing or erosion in the case of using small amount of the corrosion inhibitor on the contrary.

On this account, the development about a slurry composition that is able to maintain sufficient polishing rate and polishing speed to the copper wiring layer, while maintaining superior surface condition of the copper wiring layer after polishing by sufficiently inhibiting dishing or erosion generated in the copper wiring layer is continuously being required.

In addition, the polishing to the copper wiring layer is generally carried out according to the following method. That is, after forming a polishing stop layer including tantalum or titanium, and a copper wiring layer on a substrate successively, the excessively deposited copper wiring layer is polished by the CMP method and then the polishing of the copper wiring layer is finished by stopping the polishing when the surface of the polishing stop layer is exposed. Therefore, it is required for the slurry composition for CMP to have high polishing rate and polishing speed to the copper wiring layer and to have low polishing rate and polishing speed to the polishing stop layer, in order to polish and planarize the copper wiring layer preferably by the method (that is, high polishing selectivity is required between the copper wiring layer and the polishing stop layer).

However, the slurry compositions developed up to now does not satisfy the high polishing selectivity, and it is continuously required to develop the slurry composition having higher polishing selectivity.

### SUMMARY OF THE INVENTION

It is an aspect of the present invention to provide a slurry composition for chemical mechanical polishing (CMP) that can maintain good polishing rate and polishing speed to the target layer, and yet has a high polishing selectivity to the target layer against the other layers and can maintain superior surface condition of the target layer after polishing,

It is another aspect of the present invention to provide a chemical mechanical polishing method (CMP method) using the slurry composition.

The present invention provides an aqueous slurry composition for CMP, including abrasives; an oxidant; a complexing agent; and a polymeric additive including at least one selected from the group consisting of a polypropyleneoxide, a propyleneoxide-ethyleneoxide copolymer, and a compound represented by the following Chemical Formula 1:

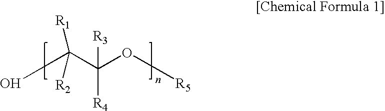

wherein, R₁˜R₄ is a hydrogen, a C1˜C6 alkyl, or a C2˜C6 alkenyl independently, R5 is a C1˜C30 alkyl or alkenyl, and n is a number of 5˜500.

The present invention also provides a CMP method comprising: contacting a polishing pad with a target layer and moving them relatively while providing the aqueous slurry composition for CMP between the target layer on a substrate and the polishing pad so as to polish the target layer.

Hereinafter, the aqueous slurry composition for CMP according to embodiments of the invention and the CMP method using the same are explained in more detail.

According to one embodiment of the present invention, the aqueous slurry composition for chemical mechanical polishing (CMP) includes abrasives; an oxidant; a complexing agent; and a polymeric additive including at least one selected from the group consisting of a polypropyleneoxide, a propyleneoxide-ethyleneoxide copolymer, and a compound represented by the following Chemical Formula 1:

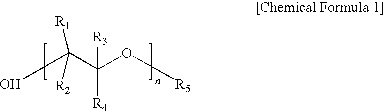

wherein, R₁˜R4 is a hydrogen, a C1˜C6 alkyl, or a C2˜C6 alkenyl independently, R5 is a C1˜C30 alkyl or alkenyl, and n is a number of 5˜500.

From the experimental results by the present inventors, it is revealed that when a certain polymeric additive such as a polypropyleneoxide, a propyleneoxide-ethyleneoxide copolymer, or a compound of Chemical Formula 1 is added to the aqueous slurry composition for CMP including abrasives, an oxidant, a complexing agent (for example, an organic acid), and so on, the target layer may be protected by the polymer and can maintain its superior surface condition after polishing by the CMP method,

It seems because these polymers show adequate hydrophobic property and thus can inhibit dishing, erosion, or scratch during polishing by protecting the surface of the target layer such as the copper wiring layer effectively.

Furthermore, it may be inhibited by using the polymeric additive that the polishing speed of the target layer such as the copper wiring layer is decreased by using an excessive corrosion inhibitor in the aqueous slurry composition. Therefore, it is possible to maintain superior polishing speed of the target layer in the CMP method, and it is also possible to maintain superior polishing selectivity to the target layer against the insulating layers such as a silicon oxide layer or the polishing stop layer such as a tantalum or titanium-containing layer, and the like.

Therefore, the aqueous slurry composition for CMP can maintain superior polishing speed and polishing rate to the target layer, and yet can show excellent polishing selectivity to the target layer against the different layers and maintain superior surface condition of the target layer after polishing by inhibiting the generation of scratch, and the like. Therefore, the aqueous slurry composition for CMP may be used preferably to polish or planarize the target layer, like the copper wiring layer, by the CMP method.

Hereinafter, each constituent of the aqueous slurry composition for CMP is explained in more detail.

The aqueous slurry composition for CMP includes the abrasives for the mechanical polishing of the target layer. Common abrasives those have been used to the slurry composition for CMP may be used unlimitedly, and metal oxide abrasives, organic abrasives, or organic-inorganic complex abrasives may be used for example.

For Example, silica abrasives, alumina abrasives, ceria abrasives, zirconia abrasives, titania abrasives, or zeolite abrasives may be used as the metal oxide abrasives, and 2 or more kinds of abrasives selected from them may be used.

Furthermore, the metal oxide abrasives prepared by any method, such as a fuming method, a sol-gel method, and the like may be used unlimitedly.

Furthermore, styrene-based polymer abrasives such as a polystyrene or a styrene-based copolymer, acryl-based polymer abrasives such as a polymethacrylate, a acryl-based copolymer or a methacryl-based copolymer, polyvinylchloride abrasives, polyamide abrasives, polycarbonate abrasives, polyimide abrasives, and the like may be used unlimitedly as the organic abrasives, and the spherical polymer abrasives having a single structure or a core/shell structure consisting of the polymer selected from them may be used without limiting their shape. Furthermore, the polymer abrasives obtained by any method like an emulsion polymerization or a suspension polymerization may be used as the organic abrasives.

Furthermore, it is needless to say that the organic-inorganic complex abrasives formed by compounding the organic materials, like the polymers, and the inorganic materials, like the metal oxides, can be also used as the abrasives.

However, it is preferable to use the silica abrasives as the abrasives by considering the polishing rate or polishing speed to the target layer such as the copper wiring layer or the proper surface protection.

Furthermore, the abrasives may have an average diameter of 10 to 500 nm by considering the proper polishing speed to the target layer and the dispersion stability in the slurry composition. For example, the average diameter of primary particles of the abrasives may be 10 to 200 nm, and preferably 20 to 100 nm based on a SEM measurement when the metal oxide abrasives are used, and the average diameter of primary particles of the abrasives may be 10 to 500 nm, and preferably 50 to 300 nm when the organic abrasives are used. The polishing speed to the target layer may be decreased when the size of the abrasives becomes excessively small, and, on the contrary, the dispersion stability of the abrasives in the slurry composition may be decreased when the size becomes excessively large.

The abrasives may be included in the aqueous slurry composition for CMP with the content of 0.1 to 30 wt %, and preferably of 0.3 to 10 wt %. The polishing property to the target layer may be decreased when the content of the abrasives is not reach to 0.1 wt %, and the stability of the slurry composition itself may be decreased when the content exceeds 30 wt %.

Furthermore, the aqueous slurry composition for CMP includes an oxidant. The oxidant takes a role of forming an oxide film by oxidizing the target layer such as the copper wiring layer, and the polishing process of the CMP method is progressed to the target layer by eliminating the oxide film by physical and chemical polishing process.

Common oxidants those have been used to the slurry composition for CMP may be unlimitedly used as the oxidant, and a peroxide-based oxidant such as hydrogen peroxide, peracetic acid, perbenzoic acid, tert-butylhydroperoxide, and the like; a persulfate-based oxidant such as sodium persulfate, potassium persulfate (KPS), calcium persulfate, ammonium persulfate, a tetraalkyl ammonium persulfate, and the like; hypochlorous acid, potassium permanganate; iron nitrate; potassium ferricyanide; potassium periodate; sodium hypochlorite; vanadium trioxide; potassium bromate; and the like may be used as the oxidant for example.

Among the various oxidants, the persulfate-based oxidant may preferably be used. It is possible to maintain superior surface condition of the target layer after polishing by protecting the surface of the target layer with the polymeric additive while maintaining superior polishing speed or polishing rate to the target layer, by using the persulfate-based oxidant in company with the polymeric additive disclosed below.

The oxidant may be included in the aqueous slurry composition for CMP with the content of 0.1 to 10 wt %, and preferably of 0.1 to 5 wt %. The polishing speed to the target layer may be decreased when the content of the oxidant is excessively low, and the property of the copper wiring layer may be decreased when the content of the oxidant is excessively high because the surface of the target layer may excessively be oxidized or corroded and sectional corrosions remain on the finally polished target layer such as the copper wiring layer.

The aqueous slurry composition for CMP also includes a complexing agent. The complexing agent takes roles of eliminating copper ions by forming a complex with the metallic substance such as the copper of the target layer that is oxidized by the action of the oxidant, and of improving the polishing speed to the target layer. Furthermore, the complexing agent can prevent the metallic substance from re-depositing on the target layer because the complexing agent can form a chemically stable complex by holding electron pair in common with the metal substance like the copper ion. Particularly, the chemical polishing by the interaction of the complexing agent and the oxidant may be a main mechanism of polishing the target layer, when the target layer is a copper-containing layer like the copper wiring layer,

An organic acid may be used as the representative complexing agent. Particularly, an amino acid-based compound, an amine-based compound, a carboxylic acid-based compound, and the like may unlimitedly be used as the complexing agent. As specific examples of the complexing agent, alanine, glycine, cystine, histidine, asparagine, guanidine, tryptophane, hydrazine, ethylene diamine, diamino cyclohexane (for example, 1,2-diamino cyclohexane), diamino propionic acid, diamino propane (for example, 1,2-diamino propane or 1,3-diamino propane), diamino propanol, maleic acid, malic acid, tartaric acid, citric acid, malonic acid, phthalic acid, acetic acid, lactic acid, oxalic acid, pyridine carboxylic acid, pyridine dicarboxylic acid (for example, 2,3-pyridine dicarboxylic acid or 2,6-pyridine dicarboxylic acid), ascorbic acid, aspartic acid, pyrazole dicarboxylic acid, or quinaldic acid, or a salt thereof may be used. Considering the reactivity to the target layer like the copper wiring layer, the glycine may preferably be use among them.

The complexing agent may be included in the aqueous slurry composition for CMP with the content of 0.05 to 5 wt %, and preferably of 0.1 to 2 wt %. It is possible to reduce dishing or erosion generated on the surface of the target layer after polishing by including the complexing agent with said content. The surface of the target layer may be corroded and the uniformity of the target layer, namely WIWNU (Within Wafer Non-Uniformity), may be deteriorated when the complexing agent is included with excessively large the content.

Furthermore, the aqueous slurry composition for CMP according to one embodiment of the invention further includes a polymeric additive including at least one selected from the group consisting of a polypropyleneoxide, a propyleneoxide-ethyleneoxide copolymer, and a compound represented by the following Chemical Formula 1 in addition to the constituents disclosed above:

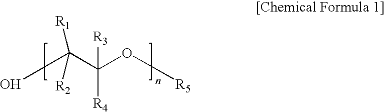

wherein, R₁˜R₄ is a hydrogen, a C1˜C6 alkyl, or a C2˜C6 alkenyl independently, R5 is a C1˜C30 alkyl or alkenyl, and n is a number of 5˜500.

The polymeric additive has an adequate hydrophobic property, and it adheres to the surface of the target layer physically, and can protect the surface of the target layer during the polishing process of using the aqueous slurry composition. Therefore, it is possible to protect the surface of the target layer from dishing, erosion, or scratch during polishing, and to maintain superior surface condition of the target layer.

As the polypropyleneoxide, the propyleneoxide-ethyleneoxide copolymer, and the compound of Chemical Formula 1, pertinent polymers already known or commercialized may unlimitedly be used, and a polymer of BRIJ Series™ (Aldrich Co.; a polyoxyethylene ether-based polymer) or a polymer of TWEEN Series™ may be used as the compound of Chemical Formula 1.

Furthermore, the polypropyleneoxide, the propyleneoxide-ethyleneoxide copolymer, and the compound of Chemical Formula 1 may have a weight average molecular weight of 300 to 100,000 respectively. By this, it is possible to protect the target layer more effectively with the polymeric additive, and to maintain the dispersion stability of the slurry properly.

From the experimental results by the present inventors, also, it is more preferable to use a propyleneoxide-ethyleneoxide copolymer including 60 to 90 wt % of ethyleneoxide repeating units and having a weight average molecular weight of 5000 to 100,000 as the polymeric additive.

The concrete reason of that such copolymer is more preferable as the polymeric additive is as follows.

The propyleneoxide-ethyleneoxide copolymer is a polymer having adequate hydrophilic property and hydrophobic property at the same time by including the hydrophilic ethyleneoxide unit and the hydrophobic propyleneoxide unit together. Thus, it is possible to increase the surface protecting effect to the target layer by using the copolymer as the polymeric additive. Particularly, the copolymer is easy to be dispersed in the aqueous slurry composition uniformly in comparison with other polymeric additives, and reduces the worries about a local irregularity on the target layer after polishing or a deterioration of the polishing performance, because the copolymer has hydrophilic property and water-solubility of some degree in company with adequate hydrophobic property. Therefore, it is possible to maintain superior surface condition of the target layer such as the copper wiring layer, and the polishing property such as polishing speed or polishing rate can be maintained more excellently by using the copolymer.

From the experimental results by the present inventors, also, it is revealed that it is possible to show more excellent surface protecting effect to the target layer such as the copper wiring layer while maintaining superior polishing speed and polishing rate to the target layer by using the propyleneoxide-ethyleneoxide copolymer having a weight average molecular weight of 5000 to 100000, and the slurry composition including the polymer has superior polishing selectivity between the target layer and the other layer such as a tantalum or titanium-containing layer, those are used as the polishing stop layer for polishing the copper wiring layer, or a silicon oxide layer. However, it may be difficult to show preferable surface protecting effect to the target layer when the molecular weight of the propyleneoxide-ethyleneoxide copolymer is excessively small, and it may also be difficult to secure preferable stability of the slurry composition including the polymer or the polishing speed to the target layer may be decreased when the molecular weight is excessively large on the contrary.

Furthermore, it is preferable that the copolymer includes the ethyleneoxide repeating unit with the content of 60 to 90 wt %, and the propyleneoxide repeating unit less than the content. Therefore, the slurry composition including the copolymer as the additive may have superior polishing selectivity because the composition shows low polishing rate to the other layers like the tantalum or titanium-containing layer or the silicon oxide layer while maintaining high polishing speed and polishing rate to the target layer such as the copper wiring layer, and dishing, erosion, or scratch may be inhibited on the surface of the target layer after polishing because the composition shows superior surface protecting effect to the target layer. On the contrary, the polishing rate to the other layers like the tantalum or titanium-containing layer or the silicon oxide layer increases and the polishing selectivity may be decreased when the content of the ethyleneoxide repeating unit is excessively low, and the surface protecting effect to the target layer is decreased and scratch or dishing may easily occur when the content of the ethyleneoxide repeating unit is excessively high.

For the reason described above, the propyleneoxide-ethyleneoxide copolymer of which the weight average molecular weight and the content of the ethyleneoxide repeating unit are properly specified may be used as the polymeric additive preferably, and thus it is possible to maintain superior surface condition of the target layer after polishing, and yet the slurry composition including the additive may show more superior polishing performances of the polishing speed and the polishing selectivity to the target layer.

In addition, the slurry composition according to one embodiment of the invention may further include a hydrophilic polymer such as a polyethylenglycol and the like as the polymeric additive in company with the polypropyleneoxide, the propyleneoxide-ethyleneoxide copolymer, or the compound represented by Chemical Formula 1. Further including the hydrophilic polymer may adequately control the hydrophilic and hydrophobic properties of the polymeric additive, and accordingly, it is possible to increase the surface protecting effect to the target layer to which the additive is used. Particularly, when the water-solubility of the polymeric additive is not sufficient, it may cause a local irregularity of the target layer after polishing or deterioration of the polishing performance because it is difficult to disperse the same uniformly in the aqueous slurry composition for CMP, and thus this point may be improved by including the polyethylenglycol and the like.

The polymeric additive may be included in the aqueous slurry composition for CMP with the content of 0.0001 to 2 wt %, and preferably of 0.005 to 1 wt %. It is possible to protect the surface of the target layer effectively, to inhibit the generation of scratch, dishing, or erosion, and to optimize the polishing selectivity between the target layer and the other layer, while maintaining superior polishing speed of the target layer like the copper wiring layer in the polishing process using the slurry composition, by including the polymeric additive with such content.

Furthermore, the aqueous slurry composition for CMP may further include DBSA (dodecylbenzenesulfonic acid), DSA (dodecyl sulfate), or a salt thereof in order to increase the solubility of the polymeric additive.

Furthermore, the aqueous slurry composition for CMP according to one embodiment of the invention may further include a corrosion inhibitor or a pH control agent in addition to the constituents disclosed above.

The corrosion inhibitor is a constituent added for preventing dishing and the like by inhibiting that the complexing agent severely chemically attacks the target layer at the dug parts thereof.

As the corrosion inhibitor, common materials those have been used to the slurry composition for CMP as the corrosion inhibitor may be used unlimitedly, and an azole-based compound such as benzotriazole (BTA), 4,4′-dipyridyl ethane, 3,5-pyrazole dicarboxylic acid, quinaldic acid, or a salt thereof may be used for example.

Furthermore, the corrosion inhibitor may be included in the aqueous slurry composition for CMP with the content of 0.001 to 2 wt %, and preferably of 0.01 to 1 wt %. By this, the deterioration of the polishing rate caused by the corrosion inhibitor may be reduced, and yet dishing caused by the chemical attack of the organic acid, for example, may effectively be reduced.

In addition, the aqueous slurry composition for CMP may further include a pH control agent to control the pH of the slurry adequately. As the pH control agent, a basic pH control agent such as potassium hydroxide, sodium hydroxide, aqueous ammonia, rubidium hydroxide, cesium hydroxide, sodium hydrogen carbonate, and sodium carbonate; or at least one acidic pH control agent selected from the group consisting of hydrochloric acid, nitric acid, sulfuric acid, phosphoric acid, formic acid, and acetic acid may be used, and the slurry may be diluted with a deionized water in order to prevent the coagulation of the slurry caused by a local pH variation when using a strong acid or a strong base.

Considering proper pH of the slurry composition to be controlled, a man skilled in the related art may use the pH control agent with a proper content. For example, the pH of the aqueous slurry composition for CMP may be controlled to be preferably in the range of 3 to 11 by considering the polishing rate and the polishing selectivity, and the pH control agent may be used with a proper content by considering the proper pH range.

Furthermore, the aqueous slurry composition for CMP further include water or an aqueous solvent as a solvent for dissolving or dispersing the constituents disclosed above with the rest content.

The aqueous slurry composition for CMP can maintain superior polishing speed and polishing rate to the target layer like the copper wiring layer, and yet can effectively protect the surface, prevent the generation of dishing, erosion, or scratch, and maintain superior surface condition of the target layer after polishing, by including the certain polymeric additive.

For example, the aqueous slurry composition for CMP can effectively protect the surface of the copper layer and maintain superior surface condition after polishing, while maintaining its superior polishing rate and polishing speed of 4000 Å/min or more, preferably of 6000 Å/min or more, and more preferably of 7000 Å/min. For example, as supported by the following Examples, the surface condition of the copper layer can be maintained as good as the surface roughness (RA) of the copper layer polished by CMP is 10 nm or less, preferably 8.0 nm or less, and more preferably 7.0 nm or less, when CMP polishing the copper layer by using the aqueous slurry composition for CMP.

Furthermore, the slurry composition shows low polishing rate to the other layers such as the tantalum or titanium-containing layer used as the polishing stop layer and the silicon oxide layer used as the insulating layer of the semiconductor device, while maintaining high polishing rate to the target layer like the copper wiring layer. Therefore, the slurry composition can show superior polishing selectivity between the target layer and the other layers.

The aqueous slurry composition for CMP shows superior polishing selectivity between the copper layer and the tantalum layer as the polishing rates between the copper layer:the tantalum layer is 40:1 or more, preferably 60:1 or more, and more preferably 100:1 or more. Furthermore, the composition also shows superior polishing selectivity between the copper layer and the silicon oxide layer as the polishing rates between the copper layer:the silicon oxide layer is 100:1 or more, preferably 200:1 or more, and more preferably 300:1 or more.

Therefore, the aqueous slurry composition for CMP can be used very preferably for polishing or planarizing the copper wiring layer and the like by CMP method, because it can maintain superior surface condition of the target layer, while showing superior polishing rate to the target layer like the copper layer and high polishing selectivity. And particularly, the slurry composition may be used for polishing or planarizing the copper-containing layer such as the copper wiring layer of the semiconductor device.

According to the other embodiment of the invention, a chemical mechanical polishing (CMP) method using the slurry composition is provided. The CMP method includes the step of polishing the target layer by contacting a polishing pad with the target layer and moving them relatively while providing the aqueous slurry composition for CMP between the target layer on the substrate and the polishing pad of the polishing device for CMP.

In the CMP method, the preferable target layer may be the copper-containing layer such as the copper wiring layer of the semiconductor device, and the polishing stop layer including tantalum or titanium, preferably tantalum, may be formed below the target layer (e.g, the copper-containing layer). Furthermore, the polishing stop layer and the target layer may be formed on an insulating layer composed of a silicon oxide layer.

In polishing or planarizing the target layer such as the copper wiring layer by CMP method, the substrate on which the target layer is formed is positioned at the head part of the polishing device, and the target layer and the polishing pad are contacted and moved relatively (that is, rotating the substrate on which the target layer is formed, or rotating the polishing pad) while providing the slurry composition between the target layer and the polishing pad of the polishing device in a state of facing the same each other. By this, a mechanical polishing by the friction with the abrasives included in the slurry composition or the polishing pad, and a chemical polishing by the other chemical constituents of the slurry composition arise together, and the target layer is polished, and the polishing or planarization to the target layer may be completed by polishing the target layer until the upper surface of the polishing stop layer is exposed.

Particularly, in the CMP method according to the other embodiment of the invention disclosed above, it is possible to polish the target layer such as the copper-containing layer, rapidly and effectively by using the aqueous slurry composition for CMP according to one embodiment of the invention, and it is also possible to proceed the polishing or the planarization to the target layer more effectively while inhibiting the damage of the insulating layer below the polishing stop layer because the polishing selectivity between the target layer and the polishing stop layer including tantalum or titanium or the insulating layer becomes good. Furthermore, it is also possible to form a wiring layer and the like having superior surface condition and properties, because it is prevented that dishing, erosion, or scratch occurs on the surface of the target layer during the polishing process.

Therefore, it is possible to form more reliable wiring layer of a semiconductor device more effectively by the CMP method, and it can largely contribute to the preparation of a high-performance semiconductor device.

As disclosed above, the aqueous slurry composition for CMP that has superior polishing rate to the target layer and high polishing selectivity to the target layer against the other layers, and is able to maintain superior surface condition of the target layer by preventing dishing, erosion, or scratch generated on the target layer during the polishing process and the CMP method using the same are provided according to the present invention.

Particularly, it is possible to show superior effect to the target layer like the copper wiring layer by using the slurry composition and the CMP method.

Therefore, the present invention can largely contribute to the preparation of high-performance semiconductor device, because it is possible to for the copper wiring layer of the semiconductor device having superior reliability and properties by the slurry composition and the CMP method.

### BRIEF DESCRIPTION OF THE DRAWINGS

FIG. 1 shows the results of an AFM analysis after etching test in the present Experimental Examples (Examples 4, 6, 10, and Comparative Example 2), wherein the Reference is a wafer before the etching test.

### DETAILED DESCRIPTION OF THE EMBODIMENTS

Hereinafter, the function and the effect of the present invention are presented in more detail through preferable examples of the invention. However, the following examples are only for illustrating the present invention and the scope of the present invention is not limited to or by them.

### Examples 1 to 23

### Preparation of the Aqueous Slurry Composition for CMP

Firstly, the following materials were used as the constituents for preparing the aqueous slurry composition for CMP.

As the abrasives of the silica, PL-1 or PL-3L among the colloidal silica of Quartron PL series of FUSO CHEMICAL Co. was used.

As the polymeric additive of propyleneoxide-ethyleneoxide copolymer, P-65 (a copolymer of BASF Co., Mw=3500), L-64 (a copolymer of BASF Co., Mw=3880), Random (a random copolymer of Aldrich Co., Mw=2500), or the propyleneoxide-ethyleneoxide copolymers having the molecular weight and the content of the ethyleneoxide repeating units disclosed in the following Table 1 were used.

As the polymeric additive of the compound of Chemical Formula 1, BRIJ-58 (a surfactant of Aldrich Co. having polyethyleneglycol stearyl ether as the main component, Mw=1224), BRIJ-76 (a surfactant of Aldrich Co. having polyethyleneglycol stearyl ether as the main component, Mw=711), or BRIJ-78 (a surfactant of Aldrich Co. having polyethyleneglycol stearyl ether as the main component, Mw=1200) were used.

In order to increase the solubility of the polymeric additives, 500 ppm of dodecylbenzenesulfonic acid (DBSA) was added to each slurry composition.

According to the composition disclosed in the following Table 1, the aqueous slurry compositions for CMP of Examples 1 to 23 were prepared by the following method.

Firstly, the abrasives, the complexing agent, the polymeric additive, the corrosion inhibitor, and the oxidant were introduced into a 1 L polypropylene bottle according to the composition disclosed in Table 1, and then deionized water was added thereto, dodecylbenzenesulfonic acid (DBSA) was added thereto, pH of the slurry composition was controlled by using the pH control agent, and the total weight of the composition was adjusted. Finally, the aqueous slurry compositions for CMP of Examples 1 to 23 were prepared by stirring the composition for 5 to 10 minutes with a high speed.

TABLE 1
Constituents of Examples 1 to 23

| | Constituents of the slurry | | | | | |
|---|---|---|---|---|---|---|
| | Abrasives | Complexing agent | Corrosion inhibitor | Oxidant | | Polymeric additive |
| Examples | (wt %) | (wt %) | (wt %) | (wt %) | pH | (wt %) |
| 1 | Silica (1.5) | Glycine (0.5) | Quinaldic acid (0.3) | APS(2) | 9.5 | L-64 (0.05), BRIJ-76 (0.025), PEG |
| | | | | | | (Mw: 1000) (0.125) |
| 2 | Silica (1.5) | Glycine (0.5) | BTA (0.0005) | APS(2) | 9 | L-64 (0.05), BRIJ-76 (0.025), PEG |
| | | Phthalic acid (0.4) | | | | (Mw: 1000) (0.125) |
| 3 | Silica (1.2) | Glycine (0.5) | Quinaldic acid (0.4) | APS(2) | 9.5 | L-64 (0.05), BRIJ-76 (0.025), PEG |
| | | Pyridine carboxylic | | | | (Mw: 1000) (0.125) |
| | | acid (0.5) | | | | |
| 4 | Silica (1.2) | Glycine (0.5) | DPEA (0.15) | APS(2) | 9 | L-64 (0.05), BRIJ-76 (0.025), PEG |
| | | Pyridine carboxylic | | | | (Mw: 1000) (0.125) |
| | | acid (0.5) | | | | |
| 5 | Silica (1.5) | Glycine (1) | BTA (0.0005) | APS(2) | 9 | L-64 (0.05), BRIJ-76 (0.025), PEG |
| | | Quinaldic acid (0.3) | | | | (Mw: 1000) (0.125) |
| 6 | Silica (1.2) | Glycine (0.5) | DPEA (0.15) | APS(2) | 9.2 | P-65 (0.07), BRIJ-76 (0.07), PEG |
| | | Malic acid (0.5) | | | | (Mw: 1000) (0.07) |
| 7 | Silica (1.5) | Glycine (0.6) | DPEA (0.2) | APS(2) | 8.7 | L-64 (0.05), BRIJ-76 (0.025), PEG |
| | | | | | | (Mw: 1000) (0.125) |
| 8 | Silica (1.2) | Glycine (0.5) | Quinaldic acid (0.3) | APS(2) | 10.3 | L-64 (0.05), BRIJ-76 (0.025), PEG |
| | | Phthalic acid (0.4) | | | | (Mw: 1000) (0.125) |
| 9 | Silica (1) | Glycine (0.5) | Quinaldic acid (0.2) | APS(2) | 9.5 | P-65 (0.05), BRIJ-58 (0.025), PEG |
| | | Pyridine carboxylic | | | | (Mw: 1000) (0.125) |
| | | acid (0.5) | | | | |
| 10 | Silica (1) | Glycine (0.5) | Quinaldic acid (0.2) | APS(2) | 9.5 | Random (0.05), BRIJ-58(0.05), PEG |
| | | | | | | (Mw: 1000) (0.1) |
| 11 | Silica (1.2) | Glycine (0.6) | Quinaldic acid (0.3) | APS(2) | 9.2 | PO-EO copolymer (EO: 80%, Mw: |
| | | | | | | 11,250) (0.2) |
| 12 | Silica (1.5) | Glycine (0.5) | BTA (0.01) | APS(2) | 9.3 | PO-EO copolymer (EO: 70%, Mw: |
| | | Phthalic acid (0.4) | | | | 7,500) (0.2) |
| 13 | Silica (1.2) | Glycine (0.5) | Quinaldic acid (0.4) | APS(2) | 9.2 | PO-EO copolymer (EO: 80%, Mw: |
| | | | | | | 11,250) (0.2) |
| 14 | Silica (1.2) | Glycine (0.5) | DPEA (0.15) | APS(2) | 9.3 | PO-EO copolymer (EO: 70%, Mw: |
| | | Alanine (0.2) | | | | 13,350) (0.2) |
| 15 | Silica (1.5) | Glycine (0.7) | DPEA (0.15) | APS(2) | 9.2 | PO-EO copolymer (EO: 80%, Mw: |
| | | Quinaldic acid (0.3) | | | | 11,250) (0.2) |
| 16 | Silica (1.2) | Glycine (0.7) | DPEA (0.15) | APS(2) | 9.2 | PO-EO copolymer (EO: 80%, Mw: |
| | | Quinaldic acid (0.3) | | | | 11,250) (0.2), BRIJ-78(0.1) |
| 17 | Silica (1.5) | Glycine (0.6) | Quinaldic acid (0.2) | APS(2) | 8.7 | PO-EO copolymer (EO: 80%, Mw: |
| | | Pyridine carboxylic | | | | 16,250) (0.2) |
| | | acid (0.4) | | | | |
| 18 | Silica (1.5) | Glycine (0.5) | Quinaldic acid (0.3) | APS(2) | 9.3 | PO-EO copolymer (EO: 80%, Mw: |
| | | Phthalic acid (0.4) | | | | 11,250) (0.2), BRIJ-78(0.1) |
| 19 | Silica (1) | Glycine (0.5) | Quinaldic acid (0.2) | APS(2) | 9.5 | PO-EO copolymer (EO: 80%, Mw: |
| | | Pyridine carboxylic | | | | 11,250) (0.2) |
| | | acid (0.5) | | | | |
| 20 | Silica (1.2) | Glycine (0.6) | Quinaldic acid (0.3) | APS (2) | 9.2 | PO-EO copolymer (EO: 50%, Mw: |
| | | | | | | 11,900) (0.2) |
| 21 | Silica (1.5) | Glycine (0.5) | BTA (0.01) | APS (2) | 9.3 | PO-EO copolymer (EO: 60%, Mw: |
| | | Phthalic acid(0.4) | | | | 2,500) (0.1), BRIJ-78(0.1) |
| 22 | Silica (1.2) | Glycine (0.5) | BTA (0.01) | APS (3) | 9.3 | PO-EO copolymer (EO: 20%, Mw: |
| | | Alanine(0.2) | | | | 5,000) (0.1), PEG (Mw: 1000) (0.05), |
| | | | | | | BRIJ-78 (0.05) |
| 23 | Silica (1.5) | Glycine (0.7) | DPEA (0.15) | APS (2) | 9.2 | PO-EO copolymer (EO: 50%, Mw: |
| | | Quinaldic acid (0.3) | | | | 6,500) (0.2) |

* In the constituents of Table 1, the rest content except the content disclosed in Table 1, and the contents of dodecylbenzenesulfonic acid (DBSA) and the pH control agent not disclosed in Table 1 is water.
* In Table 1, DPEA represents 4,4′-dipyridyl ethane, BTA represents 1,2,3-benzotriazole, APS represents ammonium persulfate, PO-EO copolymer represents propyleneoxide-ethyleneoxide copolymer, EO represents ethylenoxide repeating unit, and PEG represents polyethyleneglycol, respectively.

### Comparative Examples 1 to 4

### Preparation of the Aqueous Slurry Composition for CMP

The aqueous slurry compositions for CMP of Comparative Examples 1 to 4 were prepared substantially according to the same method as in Examples 1 to 23, except that the constituents of the aqueous slurry compositions for CMP were changed like the following Table 2.

TABLE 2
Constituents of Comparative Examples 1 to 4

| | Constituents of the slurry | | | | | |
|---|---|---|---|---|---|---|
| Comparative | Abrasives | Complexing agent | Corrosion inhibitor | Oxidant | | Polymeric additive |
| Examples | (wt %) | (wt %) | (wt %) | (wt %) | pH | (wt %) |
| 1 | Silica (1.5) | Glycine (0.5) | DPEA(0.1) | APS (2) | 9.5 | PEG (Mw: 1000) (0.2) |
| | | Phthalic acid (0.4) | | | | |
| 2 | Silica (1.2) | Glycine (0.5) | Quinaldic acid (0.4) | APS (2) | 9.5 | PEG (Mw: 300) (0.2) |
| | | pyridine carboxylic | | | | |
| | | acid (0.5) | | | | |
| 3 | Silica(2) | Glycine (0.7) | Quinaldic acid (0.4) | APS (2) | 9.3 | — |
| | | pyridine carboxylic | | | | |
| | | acid (0.4) | | | | |
| 4 | Silica (1.5) | Glycine (0.6) | Quinaldic acid (0.2) | APS (2) | 8.7 | — |
| | | pyridine carboxylic | | | | |
| | | acid (0.4) | | | | |

* In the constituents of Table 2, the rest content except the content disclosed in Table 2, and the contents of dodecylbenzenesulfonic acid (DBSA) and the pH control agent not disclosed in Table 2 is water.
* In Table 2, DPEA represents 4,4′-dipyridyl ethane, APS represents ammonium persulfate, and PEG represents polyethyleneglycol, respectively.

### Experimental Example

### Tests for the Polishing Property of the Aqueous Slurry Composition for CMP

The polishing properties were tested by the following method, after carrying out polishing process by using the slurry compositions of Examples 1 to 23 and Comparative Examples 1 to 4 as disclosed below.

Firstly, a wafer on which a copper layer of 1500 nm was deposited by a physical vapor deposition (PVD) method was cut in the size of 2×2 cm², and the pieces of the wafer were dipped into 30 ml of slurry compositions of Examples 1 to 23 and Comparative Examples 1 to 4 respectively. The etching speed (Å/min) of the copper by the slurry composition was calculated by converting the weight change before and after dipping into the etched amount of the copper, and the etching speed of the copper was listed in the following Tables 3 and 4.

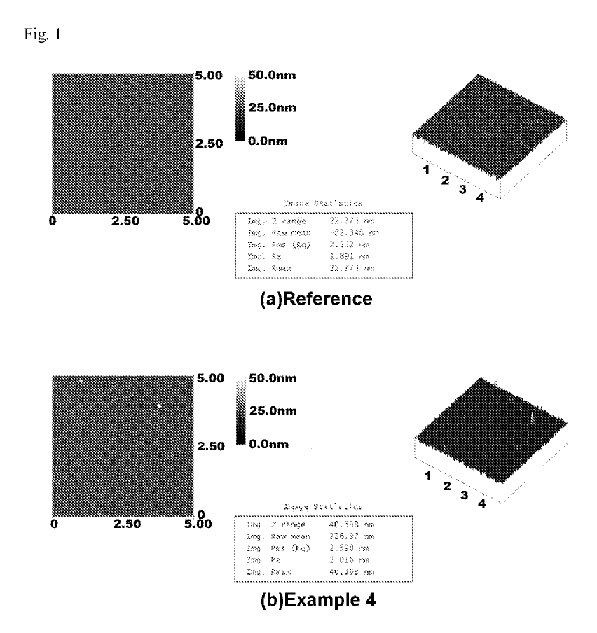

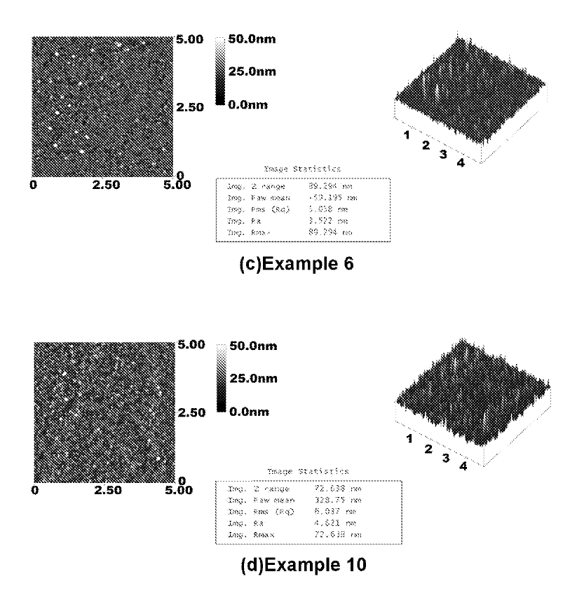

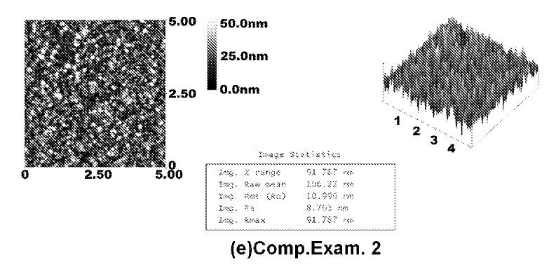

Furthermore, AFM analysis was carried out to the wafers randomly selected from Examples and Comparative Examples after the etching test, and the results are illustrated in FIG. 1 (Examples 4, 6, 10, and Comparative Example 2)

Next, the wafers on which the target layer was formed were polished by CMP method by using the slurry compositions of Examples 1 to 23 and Comparative Examples 1 to 4 for 1 minute.

### 1) Examples 1 to 10 and Comparative Examples 1 to 3

[Target Layer]

6 inches wafer on which copper layer of 15000 Å was deposited by PVD.

6 inches wafer on which tantalum layer of 3000 Å was deposited by PVD.

6 inches wafer on which silicon oxide layer of 7000 Å was deposited by PETEOS.

At this time, the concrete conditions for the polishing were as follows.

[Polishing Condition]

Polishing device: CDP 1CM51 (Logitech Co.)

Polishing pad: IC1000/SubaIV Stacked (Rodel Co.)

Platen speed: 70 rpm

Head spindle speed: 70 rpm

Pressure: 3 psi

Flow Rate of the slurry: 200 ml/min

### 2) Examples 11 to 23 and Comparative Example 4

### Target Layer

8 inches wafer on which copper layer of 15000 Å was deposited by Electroplating.

8 inches wafer on which tantalum layer of 3000 Å was deposited by PVD.

8 inches wafer on which silicon oxide layer of 7000 Å was deposited by PETEOS.

At this time, the concrete conditions for the polishing were as follows.

[Polishing Condition]

Polishing device: UNIPLA210 (Doosan DND Co.)

Polishing pad: IC1000/SubaIV Stacked (Rodel Co.)

Platen speed: 24 rpm

Head spindle speed: 100 rpm

Wafer pressure: 1.5 psi

Retainer ring pressure: 2.5 psi

Flow Rate of the slurry: 200 ml/min

The thicknesses of the copper layer, the tantalum layer, and the silicon oxide layer before and after polishing were measured as follows, and the polishing rates (polishing speed: Å/min) of the slurry composition to the copper layer, the tantalum layer, and the silicon oxide layer were obtained from the measured thickness. Also, the polishing selectivity of the slurry composition between the copper layer and the other layers (the polishing selectivity to the copper layer against the tantalum layer or the polishing selectivity to the copper layer against the silicon oxide layer) were calculated from the polishing rates to each layer. The polishing rates and the polishing selectivity to each layer were listed in Tables 3 and 4.
Measuring Method of the Thickness of Each Layer:

The thicknesses of the metal layer of the copper layer and the tantalum layer calculated according to the following Formula, after measuring the sheet resistance of each layer by using LEI1510 Rs Mapping (LEI Co.).

[Thickness of the copper layer (Å)]=[specific resistance of the copper layer (Ω/cm)/sheet resistance (Ω/square(□))]×10⁸

[Thickness of the tantalum layer (Å)]=[specific resistance of the tantalum layer (Ω/cm)/sheet resistance(Ω/square(□))]×10⁸

The thickness of the silicon oxide layer was measured by using Nanospec 6100 device (Nanometeics Co.).

In addition, the roughness (Ra) of the surface of the polished copper layer was measured by an AFM analyzing the surfaces of the copper layer before and after polishing, and the surface condition of the polished copper layer was estimated on basis of the results. For reference, the surface condition of the polished copper layer is estimated as good as the roughness of the surface of the polished copper layer is low.

Furthermore, the existence of scratch was estimated by whether scratches of 5 mm or more were generated by checking the surface of the polished copper layer with the naked eye.

The results of the surface conditions are listed in the following Tables 3 and 4.

TABLE 3
The results of the polishing property using the aqueous slurry composition for CMP of Examples 1 to 23

| | Polishing rate (/min) | | | Polishing selectivity | | | | |
|---|---|---|---|---|---|---|---|---|
| | | | Silicon | Copper layer: | Copper layer: | Etching speed of | | Surface condition |
| | Copper | Tantalum | oxide | Tantalum | Silicon oxide | Copper layer | | after polishing |
| Examples | layer | layer | layer | layer | layer | (/min) | Scratch | (Ra(nm)) |
| 1 | 9414 | 24 | 14 | 392 | 672 | 10 | Not exist | 7.1 |
| 2 | 8131 | 91 | 17 | 89 | 478 | <10 | Not exist | 4.9 |
| 3 | 8950 | 68 | 15 | 132 | 597 | <10 | Not exist | 4.6 |
| 4 | 7863 | 98 | 30 | 80 | 262 | <10 | Not exist | 5.0 |
| 5 | 8974 | 102 | 23 | 88 | 390 | <10 | Not exist | 6.3 |
| 6 | 10931 | 180 | 16 | 60 | 683 | <10 | Not exist | 6.9 |
| 7 | 6014 | 160 | 20 | 38 | 301 | <10 | Not exist | 5.4 |
| 8 | 7521 | 55 | 16 | 137 | 470 | <10 | Not exist | 4.3 |
| 9 | 9011 | 61 | 18 | 148 | 501 | <10 | Not exist | 5.3 |
| 10 | 9115 | 141 | 16 | 65 | 570 | <10 | Not exist | 5.4 |
| 11 | 6662 | 21 | 15 | 317 | 444 | 10 | Not exist | 5.2 |
| 12 | 5621 | 33 | 27 | 170 | 208 | <10 | Not exist | 4.8 |
| 13 | 6954 | 29 | 14 | 240 | 497 | 10 | Not exist | 6.4 |
| 14 | 7863 | 32 | 7 | 246 | 1123 | 10 | Not exist | 6.8 |
| 15 | 7112 | 38 | 16 | 187 | 445 | 10 | Not exist | 5.2 |
| 16 | 7725 | 42 | 21 | 184 | 368 | 15 | Not exist | 7.1 |
| 17 | 6733 | 34 | 15 | 198 | 449 | <10 | Not exist | 5.7 |
| 18 | 7001 | 37 | 15 | 189 | 467 | 10 | Not exist | 7.2 |
| 19 | 8321 | 24 | 2 | 347 | 4161 | <10 | Not exist | 5.5 |
| 20 | 6054 | 139 | 27 | 44 | 224 | 10 | Not exist | 3.3 |
| 21 | 4924 | 89 | 34 | 55 | 145 | 10 | Not exist | 4.2 |
| 22 | 4463 | 52 | 32 | 86 | 139 | <10 | Not exist | 4.2 |
| 23 | 5718 | 99 | 21 | 58 | 272 | 10 | Not exist | 6.8 |

* Surface condition before polishing: Ra = 3.2 nm

TABLE 4
The results of the polishing property using the aqueous slurry composition for CMP of Comparative Examples 1 to 4

| | Polishing rate (/min) | | | Polishing selectivity | | | | |
|---|---|---|---|---|---|---|---|---|
| | | | Silicon | Copper layer: | Copper layer: | Etching speed of | | Surface condition |
| Comparative | Copper | Tantalum | oxide | Tantalum | Silicon oxide | Copper layer | | after polishing |
| Examples | layer | layer | layer | layer | layer | (/min) | Scratch | (Ra(nm)) |
| 1 | 6114 | 112 | 31 | 54 | 197 | 10 | Exist | 12.5 |
| 2 | 8318 | 218 | 30 | 38 | 277 | 24 | Exist | 16.9 |
| 3 | 11631 | 224 | 46 | 52 | 253 | 653 | Exist | 21.4 |
| 4 | 7884 | 184 | 51 | 43 | 155 | 374 | Exist | 15.2 |

Referring to Tables 3 and 4, when using the slurry compositions of Examples 1 to 23 including a certain polymeric additive, it is recognized that superior surface condition can be maintained because the target layer has low roughness and there is no scratch even after polishing, while it is possible to maintain the polishing rate to the target layer equal to or superior than Comparative Examples 1 to 4. Furthermore, when using the slurry compositions of Examples 1 to 23, it is also recognized that the polishing selectivity equal to or largely superior than Comparative Examples 1 to 4 can be obtained because the compositions have high polishing rate to the target layer (the copper layer), and have low polishing rate to the other layer like the tantalum layer or the silicon oxide layer, on the other hand.

In comparison with, when using the slurry compositions of Comparative Examples 1 to 4 not including the polymeric additive or including polyethyleneglycol different from Examples 1 to 23 as the additive, it is recognized that scratches and the like may occur on the surface of the target layer during the polishing process and the surface condition is largely deteriorated because the roughness of the target gets high after polishing.

In addition, comparing the rest Examples 11 to 19 and Examples 20 to 23, when using the slurry compositions including the propyleneoxide-ethyleneoxide copolymer having a weight average molecular weight of 5000 to 100000 and including 60 to 90 wt % of the ethyleneoxide repeating unit as the polymeric additive, it is recognized that the polishing rate to the target layer (the copper layer) or the polishing selectivity between the target layer and the other layers (for example, the tantalum layer) is preferable. Particularly, polishing selectivity becomes good.

1. An aqueous slurry composition for chemical mechanical polishing (CMP) comprising: abrasives; an oxidant; a complexing agent; and a polymeric additive, wherein the polymeric additive comprises at least one selected from the group consisting of a polypropyleneoxide, a propyleneoxide-ethyleneoxide copolymer, and a compound represented by the following Chemical Formula 1: 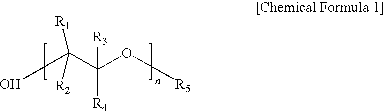
wherein, R₁, R₂, R₃ and R₄ are each and independently a hydrogen, a C1˜C6 alkyl, or a C2˜C6 alkenyl, R5 is a C1˜C30 alkyl or alkenyl, and n is a number of 5 to 500.

2. The aqueous slurry composition for CMP according to claim 1, wherein the abrasives comprise at least one selected from the group consisting of a silica abrasive, an alumina abrasive, a ceria abrasive, a zirconia abrasive, a titania abrasive, a zeolite abrasive, a styrene-based polymer abrasive, an acryl-based polymer abrasive, a polyvinylchloride abrasive, a polyamide abrasive, a polycarbonate abrasive, and a polyimide abrasive.

3. The aqueous slurry composition for CMP according to claim 1, wherein the abrasives have an average diameter of 10 to 500 nm.

4. The aqueous slurry composition for CMP according to claim 1, wherein the oxidant comprises a persulfate-based oxidant.

5. The aqueous slurry composition for CMP according to claim 4, wherein the persulfate-based oxidant comprises at least one selected from the group consisting of sodium persulfate, potassium persulfate (KPS), calcium persulfate, ammonium persulfate, and a tetraalkyl ammonium persulfate.

6. The aqueous slurry composition for CMP according to claim 1, wherein the complexing agent comprises at least one selected from the group consisting of alanine, glycine, cystine, histidine, asparagine, guanidine, tryptophane, hydrazine, ethylene diamine, diamino cyclohexane, diamino propionic acid, diamino propane, diamino propanol, maleic acid, malic acid, tartaric acid, citric acid, malonic acid, phthalic acid, acetic acid, lactic acid, oxalic acid, pyridine carboxylic acid, pyridine dicarboxylic acid, ascorbic acid, aspartic acid, pyrazole dicarboxylic acid, quinaldic acid, and a salt thereof.

7. The aqueous slurry composition for CMP according to claim 1, wherein the polymeric additive comprises a propyleneoxide-ethyleneoxide copolymer including 60 to 90 wt % of ethyleneoxide repeating units and having a weight average molecular weight of 5000 to 100000.

8. The aqueous slurry composition for CMP according to claim 1, wherein the polymeric additive further comprises a polyethyleneglycol.

9. The aqueous slurry composition for CMP according to claim 1, further comprising an corrosion inhibitor, a pH control agent, or a mixture thereof.

10. The aqueous slurry composition for CMP according to claim 9, wherein the corrosion inhibitor comprises at least one selected from the group consisting of benzotriazole, 4,4′-dipyridyl ethane, 3,5-pyrazole dicarboxylic acid, quinaldic acid, and a salt thereof.

11. The aqueous slurry composition for CMP according to claim 9, wherein the pH control agent comprises at least one basic pH control agent selected from the group consisting of potassium hydroxide, sodium hydroxide, aqueous ammonia, rubidium hydroxide, cesium hydroxide, sodium hydrogen carbonate, and sodium carbonate, or at least one acidic pH control agent selected from the group consisting of hydrochloric acid, nitric acid, sulfuric acid, phosphoric acid, formic acid, and acetic acid.

12. The aqueous slurry composition for CMP according to claim 1, comprising 0.1 to 30 wt % of the abrasives, 0.1 to 10 wt % of the oxidant, 0.05 to 5 wt % of the complexing agent, 0.0001 to 2 wt % of the polymeric additive, and remaining amount of water.

13. The aqueous slurry composition for CMP according to claim 9, comprising 0.1 to 30 wt % of the abrasives, 0.1 to 10 wt % of the oxidant, 0.05 to 5 wt % of the complexing agent, 0.001 to 2 wt % of the corrosion inhibitor, 0.0001 to 2 wt % of the polymeric additive, and remaining amount of the pH control agent and water.

14. The aqueous slurry composition for CMP according to claim 1, wherein the composition is used for polishing a copper-containing layer.

15. The aqueous slurry composition for CMP according to claim 14, wherein the copper-containing layer comprises a copper wiring layer of a semiconductor device.

16. The aqueous slurry composition for CMP according to claim 1, wherein a polishing rate to a copper layer is 4000 Å/min or more.

17. The aqueous slurry composition for CMP according to claim 1, wherein the polishing selectivity of the polishing rates between a copper layer:a tantalum layer is 40:1 or more.

18. The aqueous slurry composition for CMP according to claim 1, wherein the polishing selectivity of the polishing rates between a copper layer:a silicon oxide layer is 100:1 or more.

19. The aqueous slurry composition for CMP according to claim 1, which is enabling the surface roughness (Ra) of the copper layer polished by CMP to be 10 nm or less.

20. A chemical mechanical polishing method comprising: contacting a polishing pad with a target layer and moving them relatively while providing the aqueous slurry composition according to claim 1 between the target layer on the substrate and the polishing pad so as to polish the target layer.

21. The CMP method according to claim 20, wherein the target layer is a copper-containing layer.

22. The CMP method according to claim 21, wherein the copper-containing layer comprises a polishing stop layer and a copper wiring layer on the substrate, and the polishing to the copper-containing layer is progressed until the upper surface of the polishing stop layer is exposed.

23. The CMP method according to claim 22, wherein the polishing stop layer comprises a tantalum or titanium-containing layer.
